(19) United States
(12) Patent Application Publication
(10) Pub. No.: US 2003/0096496 A1
(43) Pub. Date: May 22, 2003

(54) Method of forming dual damascene structure

(76) Inventors: I-Hsiung Huang, Kaohsiung (TW); Jiunn-Ren Hwang, Hsinchu (TW); Kuei-Chun Hung, Hsinchu (TW); Yeong-Song Yen, Chung-Ho (TW)

Correspondence Address: J.C. Patents, Inc., Suite 250, 4 Venture, Irvine, CA, 92618, US

(21) Appl. No.: 09/990,163

(22) Filed: Nov. 20, 2001

(51) Int. Cl. H01L 21/4763

(52) U.S. Cl. 438/633

(57) ABSTRACT

A method of forming a dual damascene structure. A substrate has a conductive line thereon. A first dielectric layer, a second dielectric layer, a base anti-reflection coating and a spin-on dielectric layer are sequentially formed over the substrate. The spin-on dielectric layer, the base anti-reflection coating and the second dielectric layer are patterned to form an opening in the second dielectric layer and a first trench in the spin-on dielectric layer and the base anti-reflection coating. Using the spin-on dielectric layer and the base anti-reflection coating as a mask, the exposed first dielectric layer within the opening is removed to form a via opening that exposes a portion of the substrate. The exposed second dielectric layer within the first trench is also removed to form a second trench that exposes a portion of the first dielectric layer. Thereafter, the spin-on dielectric layer and the base anti-reflection coating are removed. A conformal barrier layer is formed over the second trench and the via opening. Finally, a conductive layer is formed over the barrier layer completely filling the second trench and the via opening.

### BACKGROUND OF THE INVENTION

1. Field of Invention

The present invention relates to a method of forming multi-level interconnects for connecting semiconductor devices. More particularly, the present invention relates to a method of manufacturing a dual damascene structure.

2. Description of Related Art

In semiconductor fabrication, various devices are interconnected by conductive lines. In general, the connection point between a conductive wire and an integrated circuit device is referred to as a contact and the connection point between conductive wires is referred to as a via. Resistance along a piece of the conductive wire and parasitic capacitance between conductive wires are major factors that are likely to affect the operating speed of a semiconductor device. In the fabrication of a deep sub-micron semiconductor device, copper is gradually replacing aluminum as the material for forming conductive wires. In the meantime, a low dielectric constant (low K) material is often employed to fabricate inter-metal dielectric layers. Ultimately, resistance-capacitance (RC) delay of the conductive wire is reduced while anti-electromigration capacity of the conductive wire is increased. This is because the capacity to resist electromigration in copper is some 30 to 100 times that of aluminum, via resistance is lowered 10 to 20 times and resistance value is lowered by 30%. However, copper is difficult to etch. Hence, a damascene process is normally employed to fabricate copper interconnects instead of a conventional patterning method.

In general, dual damascene processes can be divided into self-aligned dual damascene (SADD) processes, trench first dual damascene (TFDD) processes and via first dual damascene (VFDD) processes. In whatever process, however, maintaining device performance without changing thickness of the dielectric layer often leads to a high aspect ratio for a photoresist pattern when line width of the devices are 0.13 μm or smaller. A high aspect ratio in the photoresist pattern limits both resolution and etching rate of the photoresist layer.

Furthermore, for a via first dual damascene (VFDD) process, a gap filling material is deposited into the via opening to prevent the formation of any photoresist residue inside the via opening. However, as line width continues to decrease, completely filling an opening having an aspect ratio of five or greater with a gap-filling material is very difficult. Besides, completely removing the gap-filling material thereafter is also very difficult. A portion of the residual gap-filling material may remain inside the via opening and the corner regions of the trench forming fence structures around the via opening. These fence structures frequently produce unwanted bridges between metallic interconnects and lead to possible device failure.

In addition, etching two thick dielectric layers consecutively is also difficult. Moreover, a thick photoresist layer is required to pattern a via opening. A thick photoresist layer not only costs more to produce, but also leads to a quality deterioration problems such as peeling after photoresist and etching processes.

Consequently, a silicon oxide layer is often formed over a dielectric layer where a dual damascene structure is subsequently formed. The oxide layer serves as a mask to reduce photoresist thickness. However, silicon oxide has a high reflectivity and may produce a critical dimension exceeding a desired range. Hence, a base anti-reflection coating (BARC) is formed over the oxide layer to lower reflectivity. In general, a thicker anti-reflection coating produces a greater lowering of reflectivity in the oxide layer. Because the base anti-reflection coating produces quite a difference in height level between opening-dense regions and opening-sparse regions, especially when the coating is thick, deviation of post-development monitoring and after etching inspection (AEI) is large. Meanwhile, the loading effect between dense regions and sparse regions is increased, leading to a deterioration of etching performance. Ultimately, resolution of the photoresist pattern and depth of focus are affected.

### SUMMARY OF THE INVENTION

Accordingly, one object of the present invention is to provide a method of forming a dual damascene structure. The method includes sequentially forming a base anti-reflection coating and a spin-on dielectric layer over a dielectric layer and using the layers as an etching mask for patterning an ideal dual damascene structure.

A second object of this invention is to provide a method of forming a dual damascene structure without any need for forming a gap-filling material layer inside a via opening so that resistance-capacitance (RC) delay is within an acceptable range.

A third object of this invention is to provide a method of forming a dual damascene structure capable of increasing uniformity of critical dimension without having to increase thickness of a patterning photoresist layer. Hence, resolution and tolerance of the photoresist pattern is increased.

To achieve these and other advantages and in accordance with the purpose of the invention, as embodied and broadly described herein, the invention provides a method of forming a dual damascene structure. A substrate having a conductive line thereon is provided. A first dielectric layer, a second dielectric layer, a base anti-reflection coating and a spin-on dielectric layer are sequentially formed over the substrate. The spin-on dielectric layer, the base anti-reflection coating and the second dielectric layer are patterned to form an opening in the second dielectric layer and a first trench in the spin-on dielectric layer and the base anti-reflection coating. Using the spin-on dielectric layer and the base anti-reflection coating as a mask, the exposed first dielectric layer within the opening is removed to form a via opening that exposes a portion of the substrate. Similarly, the exposed second dielectric layer within the first trench is removed to form a second trench that exposes a portion of the first dielectric layer. Thereafter, the spin-on dielectric layer and the base anti-reflection coating are removed. A conformal barrier layer is formed over the second trench and the via opening. Finally, a conductive layer is formed over the barrier layer completely filling the second trench and the via opening.

In this invention, a base anti-reflection coating and a spin-on dielectric layer are sequentially formed over the dielectric layer. The spin-on dielectric layer serves as an etching mask. The base anti-reflection coating not only lowers back reflection so that uniformity of critical dimension is ensured; the coating is also an effective etching mask. Hence, a line width smaller than 0.1 μm and a via opening or trench having a high aspect ratio can be produced.

In addition, the anti-reflection coating and the photoresist material form independent layers because the two materials do not intermix with each other. Therefore, the spin-on dielectric layer can be directly etched first. Although the base anti-reflection coating is formed underneath the spin-on dielectric layer, the coating is capable of lowering back reflection if the coating has a sufficient thickness. Ultimately, variation of critical dimension can be suppressed.

Furthermore, this invention requires no filling of via openings by a gap-filling material to maintain resistance-capacitance delay within an acceptable range. Moreover, a relatively thin photoresist layer is needed so that resolution and depth of focus of the photoresist pattern are both increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1H are schematic cross-sectional views showing the progression of steps for fabricating a dual damascene structure according to a first preferred embodiment of this invention; and

FIGS. 2A through 2H are schematic cross-sectional views showing the progression of steps for fabricating a dual damascene structure according to a second preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

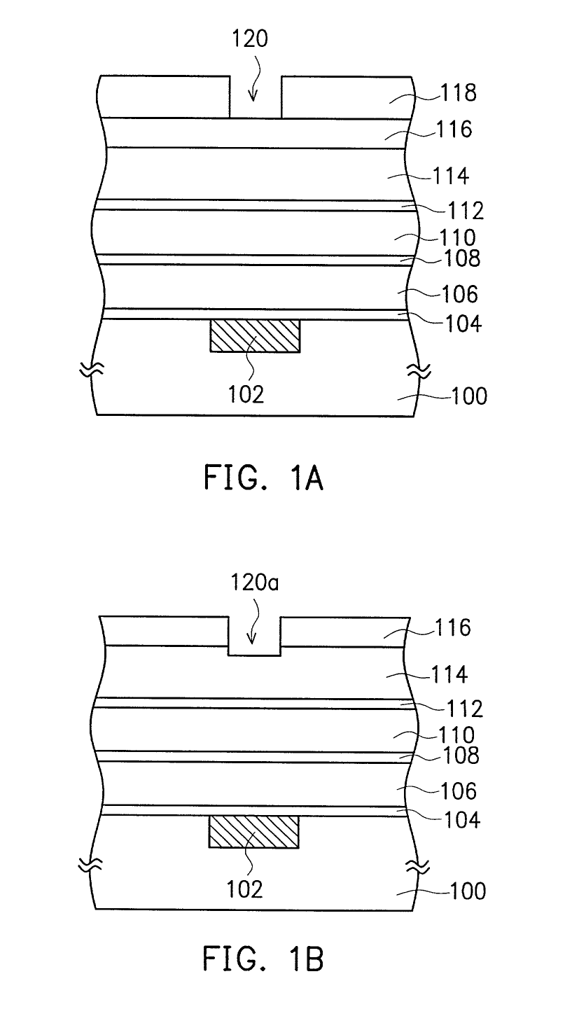

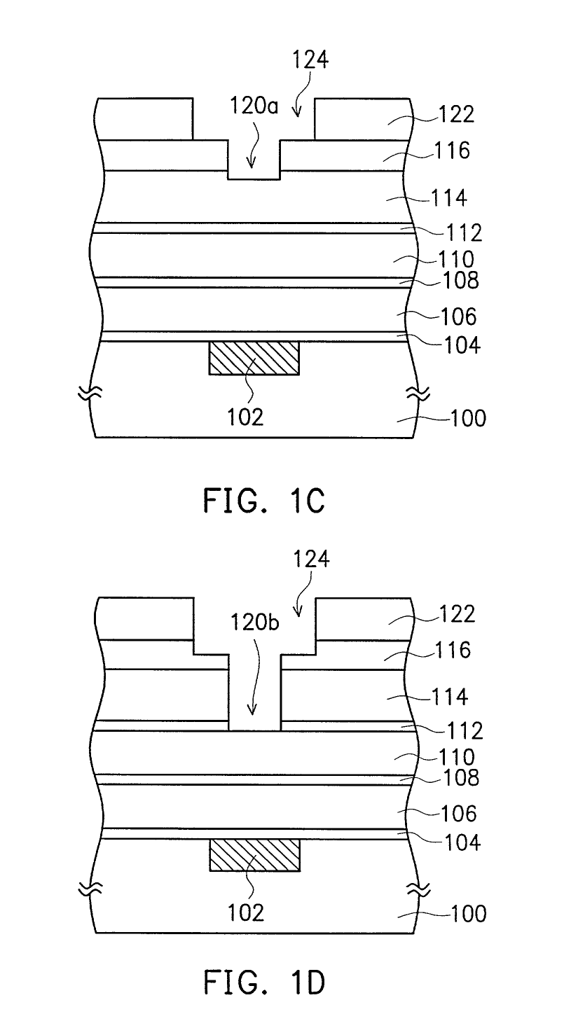

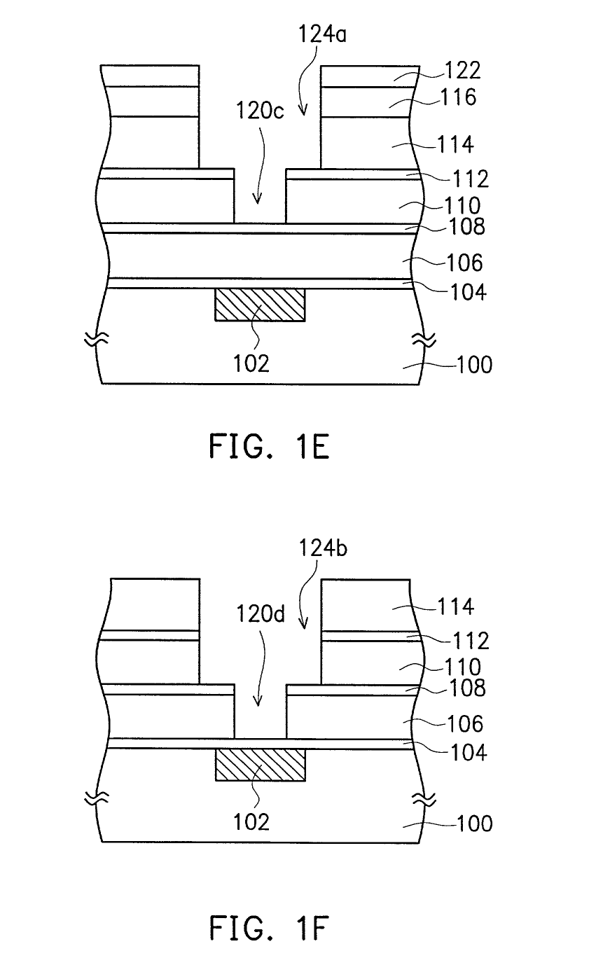

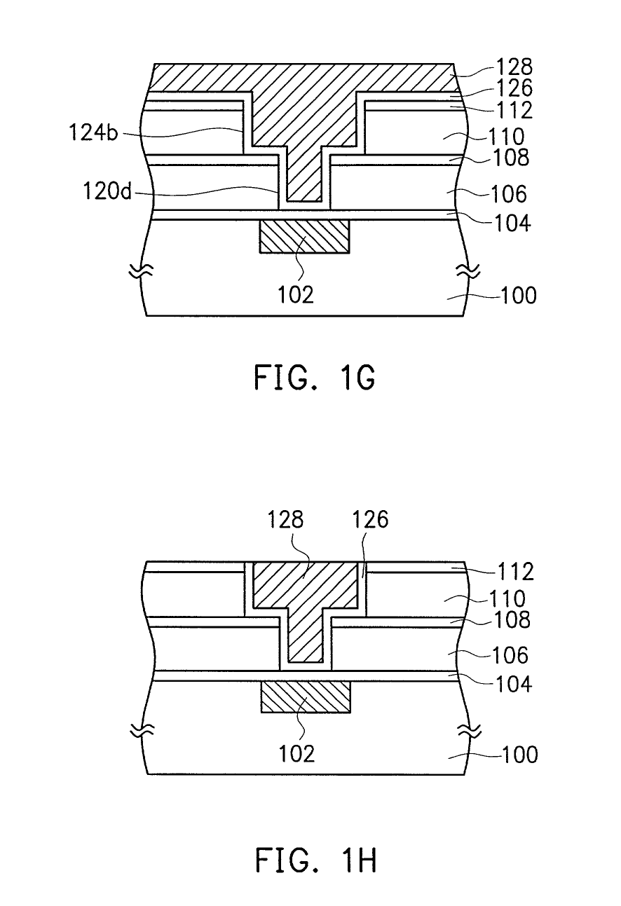

FIGS. 1A through 1H are schematic cross-sectional views showing the progression of steps for fabricating a dual damascene structure according to a first preferred embodiment of this invention. As shown in FIG. 1A, a substrate 100 (devices within the substrate 100 are not shown) having a conductive line 102 therein is provided. A passivation layer 104, a first dielectric layer 106, an etching stop layer 108, a second dielectric layer 110, a cap layer 112, an anti-reflection coating 114 and a spin-on dielectric layer 116 are sequentially formed over the substrate 100.

The passivation layer 104, the etching stop layer 108 and the cap layer 112 can be silicon nitride layers formed, for example, by chemical vapor deposition (CVD).

The first dielectric layer 106 and the second dielectric layer 110 can be made from a low dielectric constant material such as fluorinated silicate glass (FSG), undoped silicate glass (USG), poly-arylene ether (SiLK), fluorinated poly-(arylene ether) (FLARE) or hydrogen silsesquioxane (HSQ) and so on. The first dielectric layer 106 and the second dielectric layer 110 are formed, for example, by spin coating or conducting a chemical vapor deposition.

The base anti-reflection coating 114 can be made from an organic base anti-reflection material including polyimide. The base anti-reflection coating 114 is formed, for example, by spin coating. The base anti-reflection coating 114 must have a thickness greater than 1300 Å. Obviously, any film composing of non light-sensitive material and having anti-reflection property such as I-line photoresist can be used instead of the base anti-reflection coating 114.

The spin-on dielectric layer 116 can be made from a material such as spin-on glass (SOG) or silicon-rich compound (silicon content 15% to 40%). The spinon dielectric layer 116 preferably having a thickness of about 700 Å to 1600 Å is formed, for example, by spin coating.

A photoresist layer 118 is formed over the spin-on dielectric layer 116. The photoresist layer 118 having a thickness of about 1000 Å to 2500 Å can be a positive photoresist layer or a negative photoresist layer. The photoresist layer 118 is patterned to form an opening 120 for subsequently patterning a via opening. The photoresist layer 118 is patterned, for example, by conducting photolithographic and etching processes.

As shown in FIG. 1B, using the patterned photoresist layer 118 as a mask, the exposed spin-on dielectric layer 116 within the opening 120 is removed to form a opening 120a that exposes a portion of the base anti-reflection coating 114. The photoresist layer 118 is removed to expose the spin-on dielectric layer 116. The exposed spin-on dielectric layer 116 is removed, for example, by a dry etching method such as a reactive ion etching.

As shown in FIG. 1C, another photoresist layer 122 is formed over the spin-on dielectric layer 116. The photoresist layer 122 having a thickness of about 1000 Å to 2500 Å can be a positive photoresist layer or a negative photoresist layer. The photoresist layer 122 is patterned to form an opening 124 that exposes a portion of the base anti-reflection coating 114. The photoresist layer 122 is formed, for example, by conducting photolithographic and etching processes.

As shown in FIG. 1D, using the photoresist layer 122 as a mask, the exposed base anti-reflection layer 114 and the cap layer 112 within the opening 120a are removed to form an opening 120b that exposes a portion of the second dielectric layer 110. At the same time, a layer of the exposed spin-on dielectric layer 116 within the opening 124 is removed. The exposed base anti-reflection coating 114 and the cap layer 112 are removed, for example, by a dry etching method such as reactive ion etching.

As shown in FIG. 1E, using the photoresist layer 122 as a mask and the cap layer 112 and the etching stop layer 108 as etching stop, the exposed second dielectric layer 110 within the opening 120b is removed to form an opening 120c that exposes a portion of the etching stop layer 108. At the same time, the exposed spin-on dielectric layer 116 and the base anti-reflection coating 114 within the opening 124 is removed to form an opening 124c that exposes a portion of the cap layer 112. The exposed spin-on dielectric layer 116, the base anti-reflection coating 114 and the second dielectric layer 110 is removed, for example, by a dry etching method such as a reactive ion etching.

As shown in FIG. 1F, again using the photoresist layer 122 as a mask, a portion of the cap layer 112 and the etching stop layer 108 are removed to expose a portion of the second dielectric layer 110 and a portion of the first dielectric layer 106. Thereafter, the photoresist layer 122 is removed.

Using the spin-on dielectric layer 116 and the base anti-reflection coating 114 as a mask and the etching stop layer 108 and the passivation layer 104 as etching stops, the exposed first dielectric layer 106 within the opening 102c is removed to form an opening 120d that exposes the passivation layer 104. At the same time, the exposed second dielectric layer 110 within the opening 124a is removed to form an opening 124b that exposes a portion of the etching stop layer 108. The opening 120d serves as a via opening and the opening 124b serves as a trench. The exposed second dielectric layer 110 and the exposed first dielectric layer 106 are removed, for example, by a dry etching method such as a reactive ion etching. The process of removing the exposed second dielectric layer 110 and the first dielectric layer 106 also removes the spin-on dielectric layer 116.

As shown in FIG. 1G, using the base anti-reflection layer 114 as a mask, the exposed passivation layer 104 within the opening 120d and the exposed etching stop layer 108 within the opening 124b are removed. Thereafter, the base anti-reflection coating 114 is removed.

A barrier layer 126 is formed over the substrate 100. The barrier layer 126 is conformal to the profile of the opening 120d and the opening 124b and covers the cap layer 112. The barrier layer 126 can be made from a material such as tantalum nitride (TaN), titanium nitride (TiN) or titanium-silicon-nitride (TiSiN). A conductive layer 128 is formed over the barrier layer 126. The conductive layer 128 completely fills the opening 120d and the opening 124b. The conductive layer 128 is formed, for example, by physical vapor deposition (PVD) or chemical vapor deposition (CVD). The conductive layer 128 can be a copper layer, for example.

As shown in FIG. 1H, chemical-mechanical polishing is conducted to remove excess metallic and barrier material outside the opening 124b. Finally, the cap layer 112 is exposed and a dual damascene structure is formed.

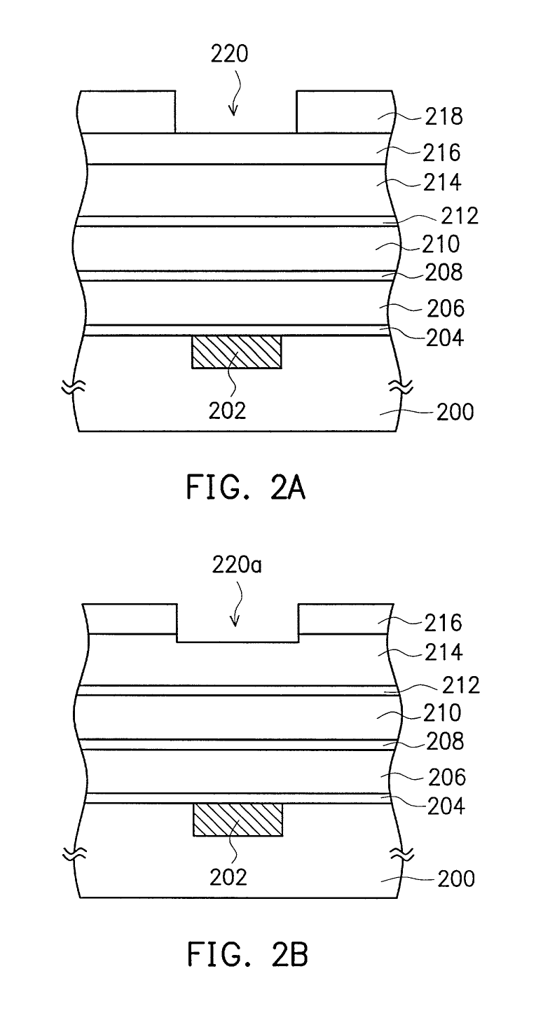

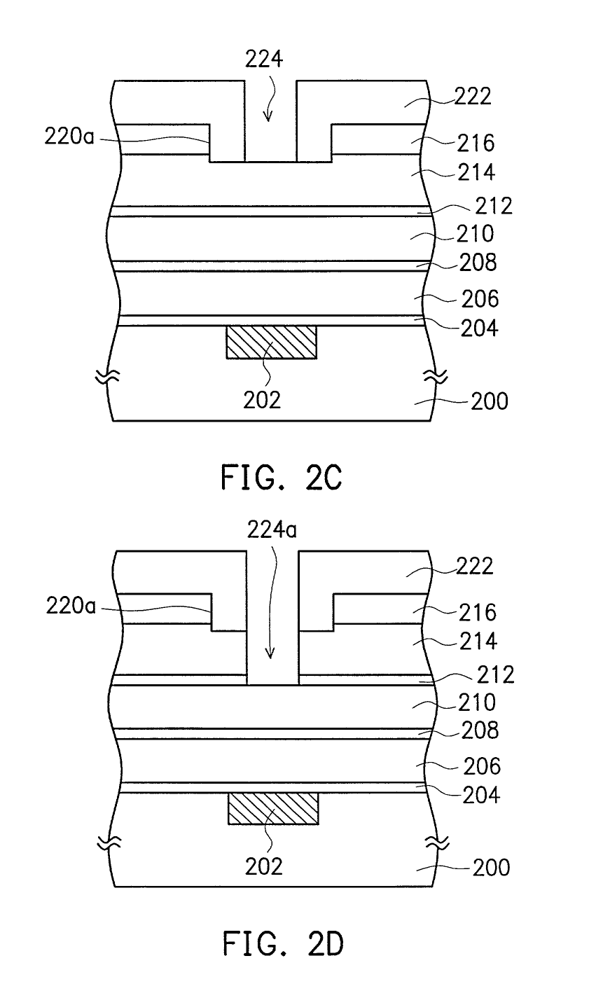

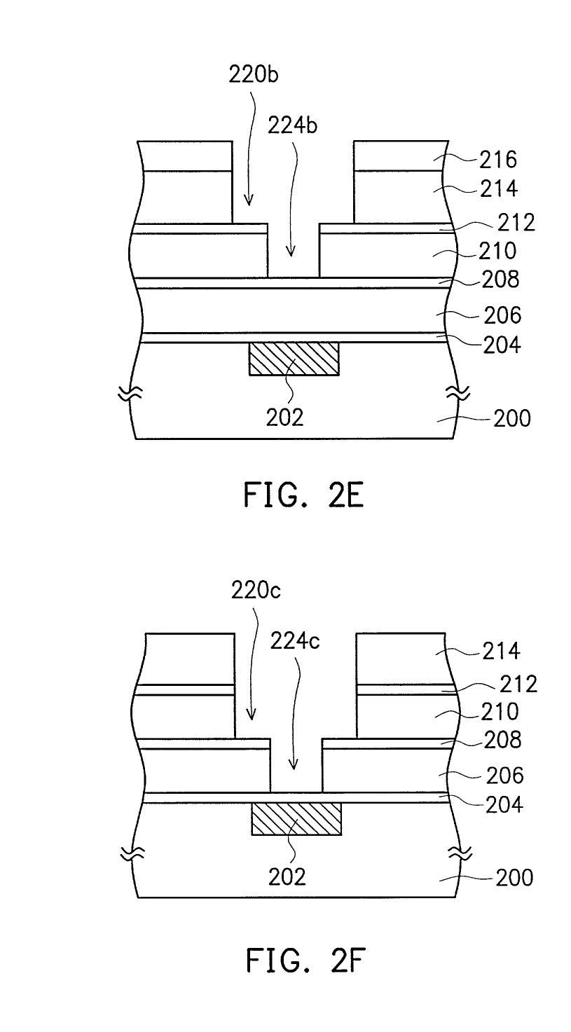

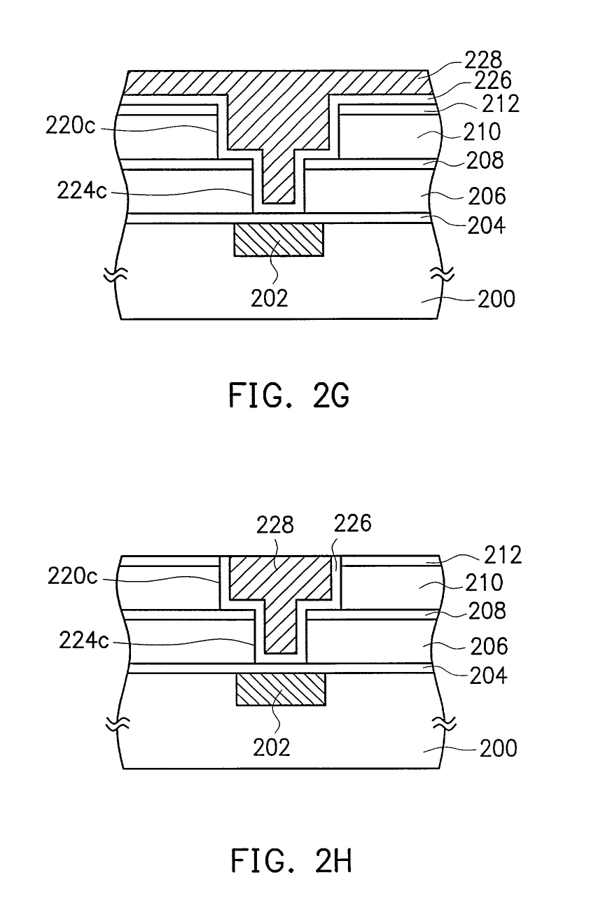

FIGS. 2A through 2H are schematic cross-sectional views showing the progression of steps for fabricating a dual damascene structure according to a second preferred embodiment of this invention. As shown in FIG. 2A, a substrate 200 (devices within the substrate 200 are not shown) having a conductive line 202 therein is provided. A passivation layer 204, a first dielectric layer 206, an etching stop layer 208, a second dielectric layer 210, a cap layer 212, an anti-reflection coating 214 and a spin-on dielectric layer 216 are sequentially formed over the substrate 200.

The passivation layer 204, the etching stop layer 208 and the cap layer 212 can be silicon nitride layers formed, for example, by chemical vapor deposition (CVD).

The first dielectric layer 206 and the second dielectric layer 210 can be made from a low dielectric constant material such as fluorinated silicate glass (FSG), undoped silicate glass (USG), poly-arylene ether (SiLK), fluorinated poly-(arylene ether) (FLARE) or hydrogen silsesquioxane (HSQ) and so on. The first dielectric layer 206 and the second dielectric layer 210 are formed, for example, by spin coating or conducting a chemical vapor deposition.

The base anti-reflection coating 214 can be made from an organic base anti-reflection material including polyimide. The base anti-reflection coating 214 is formed, for example, by spin coating. The base anti-reflection coating 214 must have a thickness greater than about 1300 Å. Obviously, any film composed of non light-sensitive material and having an anti-reflection property such as I-line photoresist can be used instead of the base anti-reflection coating 214.

The spin-on dielectric layer 216 can be made from a material such as spin-on glass (SOG) or silicon-rich compound. The silicon-rich compound may have a percentage content of silicon of about 15% to 40%. The spin-on dielectric layer 216 preferably having a thickness of about 7000 Å to 1600 Å is formed, for example, by spin coating.

A photoresist layer 218 is formed over the spin-on dielectric layer 216. The photoresist layer 218 having a thickness of about 1000 Å to 2500 Å can be a positive photoresist layer or a negative photoresist layer. The photoresist layer 218 is patterned to form an opening 220 for subsequently patterning a trench. The photoresist layer 218 is patterned, for example, by conducting photolithographic and etching processes.

As shown in FIG. 2B, using the photoresist layer 218 as a mask, the exposed spin-on dielectric layer 216 within the opening 220 is removed to form an opening 220a that exposes a portion of the base anti-reflection coating 214. The photoresist layer 218 is removed to expose the spin-on dielectric layer 216. The exposed spin-on dielectric layer 216 is removed, for example, by a dry etching method such as a reactive ion etching.

As shown in FIG. 2C, another photoresist layer 222 is formed over the substrate 200. The photoresist layer 222 having a thickness of about 1000 Å to 2500 Å can be a positive photoresist layer or a negative photoresist layer. The photoresist layer 222 is patterned to form an opening 224 that exposes a portion of the base anti-reflection coating 214. The opening 224 is used for patterning a via opening. The photoresist layer 222 is patterned, for example, by conducting photolithographic and etching processes.

As shown in FIG. 2D, using the photoresist layer 222 as a mask, the exposed base anti-reflection coating 214 and the cap layer 212 within the opening 224 are removed to form an opening 224a that exposes a portion of the second dielectric layer 210. The exposed base anti-reflection coating 214 and the cap layer 212 is removed, for example, by a dry etching method such as a reactive ion etching.

As shown in FIG. 2E, the photoresist layer 222 is removed. Using the spin-on dielectric layer 216 and the base anti-reflection coating 214 as a mask and the cap layer 212 and the etching stop layer 208 as etching stops, the exposed second dielectric layer 210 within the opening 224a is removed to form an opening 224b that exposes a portion of the etching stop layer 208. At the same time, the exposed base anti-reflection coating 214 within the opening 220a is removed to form an opening 220b that exposes a portion of the cap layer 212. The exposed base anti-reflection coating 214 and the cap layer 210 are removed, for example, by a dry etching method such as reactive ion etching.

As shown in FIG. 2F, using the spin-on dielectric layer 216 and the base anti-reflection coating 214 as a mask, a portion of the cap layer 212 is removed to expose a portion of the second dielectric layer 210 and a portion of the etching stop layer 208 is removed to expose a portion of the first dielectric layer 206.

Using the spin-on dielectric layer 216 and the base anti-reflection coating 214 as a mask and the etching stop layer 208 and the passivation layer 204 as etching stops, the exposed first dielectric layer 206 within the opening 224b is removed to form an opening 224c that exposes a portion of the passivation layer 204. In the meantime, the exposed second dielectric layer 210 within the opening 220b is removed to form an opening 220c that exposes a portion of the etching stop layer 208. The opening 224c serves as a via opening and the opening 220c serves as a trench. The exposed second dielectric layer 210 and the first dielectric layer 206 are removed, for example, by a dry etching method such as a reactive ion etching. The process of removing a portion of the first dielectric layer 206 and the second dielectric layer 210 also removes the spin-on dielectric layer 216.

As shown in FIG. 2G, using the base anti-reflection coating 214 as a mask, the exposed etching stop layer 208 within the opening 220c and the exposed passivation layer 204 within the opening 224c are removed. Thereafter, the base anti-reflection coating 214 is removed.

A barrier layer 226 is formed over the substrate 200. The barrier layer 226 is conformal to the profile of the opening 220c and the opening 224c and covers the cap layer 212. The barrier layer 226 can be made from a material such as tantalum nitride (TaN), titanium nitride (TiN) or titanium-silicon-nitride (TiSiN). A conductive layer 228 is formed over the barrier layer 226. The conductive layer 228 completely fills the opening 220c and the opening 224c. The conductive layer 228 is formed, for example, by physical vapor deposition (PVD) or chemical vapor deposition (CVD). The conductive layer 228 can be a copper layer, for example.

As shown in FIG. 2H, chemical-mechanical polishing is conducted to remove excess metallic and barrier material outside the openings 220c. Finally, the cap layer 212 is exposed and a dual damascene structure is formed.

In conclusion, the advantages of this invention include:

1. In this invention, a base anti-reflection coating and a spin-on dielectric layer are sequentially formed over a dielectric layer. The spin-on dielectric layer serves as an etching mask. The base anti-reflection coating not only lowers back reflection so that uniformity of critical dimension is ensured; the coating serves also as an effective etching mask. Hence, a line width smaller than 0.1 μm and a via opening or trench having a high aspect ratio can be produced.

2. The anti-reflection coating is formed underneath the spin-on dielectric layer. When the base anti-reflection coating has a definite thickness, back reflection is effectively suppressed leading to less variation in the critical dimension. Furthermore, since the base anti-reflection coating and the photoresist layer will no intermix with each other, the spin-on dielectric layer can be etched first.

3. This invention requires no filling of via opening by a gap-filling material to maintain a resistance-capacitance delay within an acceptable range.

4. Since the base anti-reflection coating and the spin-on dielectric layer can serve as a mask, a relatively thin photoresist layer is needed. Hence, resolution and depth of focus of the photoresist pattern are both increased leading to a lower production cost.

5. The base anti-reflection coating, the spin-on dielectric layer and the photoresist layer are formed by spin coating. Hence, all these processing may be conducted inside the same machine. Ultimately, a highly planar base anti-reflection coating is produced and loading effect of an anti-reflection coating due to a difference in height level over a dense region and a sparse region is minimized.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a dual damascene structure, comprising:
providing a substrate;
sequentially forming a passivation layer, a first dielectric layer, an etching stop layer, a second dielectric layer, a cap layer, a base anti-reflection coating and a spin-on dielectric layer over the substrate;
patterning the spin-on dielectric layer, the base anti-reflection coating, the cap layer and the second dielectric layer so that an opening is formed in the cap layer and the second dielectric layer and a first trench are formed in the spin-on dielectric layer and the base anti-reflection coating;
removing the exposed etching stop layer and the cap layer within the opening and the first trench using the spin-on dielectric layer and the base anti-reflection coating as a mask;
removing the exposed first dielectric layer and the second dielectric layer within the opening and the first trench using the spin-on dielectric layer and the base anti-reflection coating as a mask;
removing the exposed passivation layer within the opening using the spin-on dielectric layer and the base anti-reflection coating as a mask, for forming a via opening that exposes a portion of the substrate as well as removing the exposed etching stop layer within the first trench for forming a second trench that exposes a portion of the first dielectric layer;
removing the spin-on dielectric layer and the base anti-reflection layer;
forming a conformal barrier layer over the second trench and the via opening; and
forming a conductive layer over the barrier layer such that the conductive layer completely fills the second trench and the via opening.

2. The method of claim 1, wherein forming an opening in the cap layer and the second dielectric layer as well as forming a first trench in the spin-on dielectric layer and the base anti-reflection coating further include:
forming a patterned first photoresist layer over the spin-on dielectric layer for patterning an opening;
removing a portion of the spin-on dielectric layer to form a first opening using the patterned first photoresist layer as a mask, wherein the first opening exposes a portion of the base anti-reflection coating;
removing the patterned first photoresist layer;
forming a patterned second photoresist layer over the substrate for patterning the first trench;
removing a portion of the base anti-reflection coating and the cap layer using the patterned second photoresist layer as mask for exposing the second dielectric layer;
removing the exposed second dielectric layer within the first opening using the patterned second photoresist layer as a mask, so that an opening is formed in the second dielectric layer, and removing a portion of the spin-on dielectric layer and the base anti-reflection coating, wherein the first trench is formed in the spin-on dielectric layer and the base anti-reflection coating; and
removing the patterned second photoresist layer.

3. The method of claim 1, wherein forming an opening in the cap layer and the second dielectric layer as well as forming a first trench in the spin-on dielectric layer and the base anti-reflection coating further include:
forming a patterned first photoresist layer over the spin-on dielectric layer for patterning the first trench;
removing a portion of the spin-on dielectric layer using the patterned first photoresist layer as a mask, for forming a first opening, wherein the first opening exposes a portion of the base anti-reflection coating;
removing the patterned first photoresist layer;
forming a patterned second photoresist layer over the substrate for patterning an opening;
removing a portion of the base anti-reflection coating and the cap layer using the patterned second photoresist layer as a mask, for forming a second opening, wherein the second opening exposes a portion of the second dielectric layer;
removing the patterned second photoresist layer; and
removing the exposed second dielectric layer within the second opening using the spin-on dielectric layer as a mask, so that a via opening is formed in the second dielectric layer, and removing the exposed base anti-reflection coating within the first opening, wherein the first trench is formed in the spin-on dielectric layer and the base anti-reflection coating.

4. The method of claim 1, wherein material forming the base anti-reflection coating is selected from a group consisting of polyimide and I-line photoresist.

5. The method of claim 1, wherein material forming the spin-on dielectric layer is selected from a group consisting of spin-on glass and silicon-rich compound.

6. The method of claim 5, wherein the silicon-rich compound has a percentage of silicon of about 15% to 40%.

7. The method of claim 1, wherein the spin-on dielectric layer has a thickness between about 700 Å to 1600 Å.

8. The method of claim 1, wherein forming the base anti-reflection coating includes spin coating.

9. The method of claim 1, wherein the base anti-reflection coating has a thickness greater than 1300 Å.

10. The method of claim 1, wherein material forming the passivation layer, the etching stop layer and the cap layer includes silicon nitride.

11. The method of claim 1, wherein material forming the first dielectric layer and the second dielectric layer is selected from a group consisting of fluorinated silicate glass (FSG), undoped silicate glass (USG), poly-arylene ether (SiLK), fluorinated poly-(arylene ether) (FLARE) and hydrogen silsesquioxane (HSQ).

12. A method of forming a dual damascene structure, comprising:
providing a substrate having a conductive line thereon;
sequentially forming a first dielectric layer, a second dielectric layer, a base anti-reflection coating and a spin-on dielectric layer over the substrate;
patterning the spin-on dielectric layer, the base anti-reflection coating and the second dielectric layer to form a first opening and a second opening in the spin-on dielectric layer and the base anti-reflection coating;
removing the exposed first dielectric layer within the first opening using the spin-on dielectric layer and the base anti-reflection coating as a mask, for forming a via opening, wherein the via opening exposes a portion of the substrate, and removing the exposed second dielectric layer within the second opening for forming a trench, wherein the trench exposes a portion of the first dielectric layer;
removing the spin-on dielectric layer and the base anti-reflection layer;
forming a conformal barrier layer over the trench and the via opening; and
forming a conductive layer over the barrier layer, wherein the conductive layer completely fills the trench and the via opening.

13. The method of claim 12, wherein material forming the base anti-reflection coating is selected from a group consisting of polyimide and I-line photoresist.

14. The method of claim 12, wherein material forming the spin-on dielectric layer is selected from a group consisting of spin-on glass and silicon-rich compound.

15. The method of claim 14, wherein the silicon-rich compound has a percentage of silicon of about 15% to 40%.

16. The method of claim 12, wherein the spin-on dielectric layer has a thickness of about 700 Å to 1600 Å.

17. The method of claim 12, wherein forming the base anti-reflection coating includes spin coating.

18. The method of claim 12, wherein the base anti-reflection coating has a thickness greater than about 1300 Å.

19. The method of claim 12, wherein material forming the first dielectric layer and the second dielectric layer is selected from a group consisting of fluorinated silicate glass (FSG), undoped silicate glass (USG), poly-arylene ether (SiLK), fluorinated poly-(arylene ether) (FLARE) and hydrogen silsesquioxane (HSQ).
